(19) United States
(12) Patent Application Publication
(10) Pub. No.: US 2018/0215952 A1
(43) Pub. Date: Aug. 2, 2018

(54) POLISHING COMPOSITION

(71) Applicant: FUJIMI INCORPORATED, Kiyosu-shi, Aichi (JP)

(72) Inventors: Shogo ONISHI, Kiyosu-shi, Aichi (JP); Takahiro UMEDA, Kiyosu-shi, Aichi (JP)

(73) Assignee: FUJIMI INCORPORATED, Kiyosu-shi, Aichi (JP)

(21) Appl. No.: 15/505,672

(22) PCT Filed: Jul. 2, 2015
(86) PCT No.: PCT/JP2015/069198

§ 371 Date: Feb. 22, 2017

(30) Foreign Application Priority Data
Sep. 8, 2014 (JP) 2014-182583

(51) Int. Cl. C09G 1/02

(52) U.S. Cl. CPC C09G 1/02; H01L 21/304

(57) ABSTRACT

The present invention provides a polishing composition which can achieve a high polishing speed for the layer containing copper and at the same time, can suppress dissolution of the layer containing cobalt, in polishing an object to be polished having a layer containing copper and a layer containing cobalt.

Disclosed is a polishing composition used for polishing an object to be polished having a layer containing copper and a layer containing cobalt, which comprises an oxidizing agent, and at least one cobalt dissolution inhibitor selected from the group consisting of a compound having a nitrogen-containing 5-membered ring structure, and an aminocarboxylic acid having two or more carboxyl groups.

### TECHNICAL FIELD

The present invention relates to a polishing composition. More particularly, the present invention relates to a polishing composition suitable for polishing an object to be polished having a layer containing copper and a layer containing cobalt.

### BACKGROUND ART

In recent years, new microprocessing technologies have been developed along with high-level integration and performance enhancement of LSI (Large Scale Integration). Chemical mechanical polishing (hereinafter, also simply referred to as CMP) is one of such technologies, and is a technology that is frequently utilized for the flattening of an interlayer insulating film, formation of a metal plug, and formation of embedded wiring (damascene wiring) in a LSI production process, particularly a multilayer wiring forming process. A damascene wiring technology is capable of simplifying a wiring process and enhancing product yield and reliability, and it is considered that the range of applications will be expanded in the future.

A general method of CMP involves attaching a polishing pad onto a circular polishing table (platen), immersing the surface of the polishing pad in a polishing agent, pressing the polishing pad on a surface of a substrate on which a metal film has been formed, subsequently rotating the polishing table while predetermined pressure (hereinafter, also simply described as polishing pressure) is applied through a back surface of the substrate, and eliminating a convex part in the metal film by means of mechanical friction between a polishing agent and the convex part in the metal film.

Incidentally, regarding the damascene wiring, copper has been now mainly used as the wiring metal due to its low resistance, and thus it is speculated that the range of use of copper will be expanded in the future even to memory devices, a representative example of which is DRAM (Dynamic Random Access Memory). Furthermore, as a layer beneath a conductive substance that forms the damascene wiring (copper, a copper alloy or the like), a barrier layer is formed in order to prevent diffusion of the conductive substance into an interlayer insulating film. As a material that constitutes the barrier layer, tantalum, a tantalum alloy, a tantalum compound or the like has been hitherto used (see, for example, JP 2001-85372 A and JP 2001-139937 A).

In recent years, along with a tendency for micronization of wiring, a phenomenon has occurred in which plating of copper does not proceed smoothly, and voids (phenomenon in which there is no substance existing locally) occur. Thus, in order to solve the inconveniences as described above, investigation has been conducted in recent years on supplementing adhesiveness by using cobalt or a cobalt compound, which is likely to have affinity with copper, between a barrier layer and the copper. It has also been investigated to use cobalt or a cobalt compound in a barrier layer.

### SUMMARY OF INVENTION

A damascene wiring technology generally involves an operation of forming a barrier layer and a metal wiring layer on an insulator layer provided with trenches, and then eliminating excess wiring material (metal wiring layer) and barrier layer in the part other than the wiring portion by CMP.

However, in recent years, as described above, a damascene wiring technology using a layer containing cobalt has been investigated, and there has been a problem that cobalt is easily dissolved during the polishing of the layer containing cobalt by CMP. More specifically, in regard to the damascene wiring technologies, there has been a problem that when CMP is performed in order to eliminate excess barrier layer and metal wiring layer, a layer containing cobalt is dissolved, to generate pits or corrosion on its surface. As such, when pits or corrosion occurs on a layer containing cobalt during CMP, there is a risk that function of the layer containing cobalt may be impaired.

Therefore, there is a demand for a polishing composition which can achieve a high polishing speed for the layer containing copper and at the same time, can suppress dissolution of the layer containing cobalt, in polishing an object to be polished having a layer containing copper and a layer containing cobalt.

Therefore, it is an object of the present invention to provide a polishing composition which can achieve a high polishing speed for the layer containing copper and at the same time, can suppress dissolution of the layer containing cobalt, in polishing an object to be polished having a layer containing copper and a layer containing cobalt.

The present inventors have repeatedly conducted thorough investigations in order to solve the problems as described above. As a result, the present inventors have found that the above-described problems can be solved by using a polishing composition including an oxidizing agent and a cobalt dissolution inhibitor selected from a particular group of compounds. More specifically, when at least one organic compound selected from the group consisting of a compound having a nitrogen-containing 5-membered ring structure, and a compound having two or more carboxyl groups, is used as a cobalt dissolution inhibitor, dissolution of cobalt can be effectively suppressed, while a high polishing speed for a layer containing copper is manifested. The present inventors have thus completed the present invention based on these findings.

That is, the present invention relates to a polishing composition used for polishing an object to be polished having a layer containing copper and a layer containing cobalt, the polishing composition including an oxidizing agent and a cobalt dissolution inhibitor, wherein the cobalt dissolution inhibitor is at least one selected from the group consisting of a compound having a nitrogen-containing 5-membered ring structure, and a compound having two or more carboxyl groups.

### BRIEF DESCRIPTION OF DRAWINGS

FIG. 1 is a SEM (scanning electron microscopic) photograph showing a cross-section of a pattern obtained after polishing a cobalt-copper patterning wafer using a polishing composition of Example 10, and the reference numeral “1” represents a barrier layer (Ta layer), and the reference numeral “2” represents a layer containing copper.

FIG. 2 is a SEM (scanning electron microscopic) photograph showing a cross-section of a pattern obtained after polishing a cobalt/copper patterning wafer using a polishing composition of Comparative Example 12, and the reference numeral “1” represents a barrier layer (Ta layer), and the reference numeral “2” represents a layer containing copper.

### DESCRIPTION OF EMBODIMENTS

The present invention is to provide a polishing composition that is used for the purpose of polishing an object to be polished having a layer containing copper and a layer containing cobalt, the polishing composition including an oxidizing agent and a cobalt dissolution inhibitor, in which the cobalt dissolution inhibitor is at least one selected from the group consisting of a compound having a nitrogen-containing 5-membered ring structure and a compound having two or more carboxyl groups. By such a configuration, dissolution of a layer containing cobalt can be effectively suppressed, while a high polishing speed for a layer containing copper is manifested.

Since cobalt that constitutes a barrier layer or the like is dissolved under polishing conditions for a general barrier layer (and a metal wiring layer), the present inventors have studied on various compounds as a cobalt dissolution inhibitor. As a result, surprisingly, the present inventors have found that an excellent cobalt dissolution inhibitory effect can be attained when at least one selected from the group consisting of a compound having a nitrogen-containing 5-membered ring structure, and a compound having two or more carboxyl groups is added to a polishing composition. Although a mechanism for this may be explained as follows, the following mechanism is only based on speculations, and the present invention is not intended to be limited to the following mechanism.

Cobalt that constitutes a barrier layer is easily oxidized by water or the like that is used in the polishing under weakly acidic to alkaline conditions (pH in the approximate range of 4 to 12) which are general polishing conditions for a barrier layer (and a metal wiring layer). As a result, it is considered that cobalt having its surface oxidized can be easily dissolved when CMP is performed.

It is speculated that an outermost surface of cobalt is covered with a hydroxyl group (—OH) or the like. It is contemplated that the cobalt dissolution inhibitor according to the present invention coordinates to or forms a complex with the hydroxyl group, to form a protective film on the cobalt surface. As a result, it is believed that dissolution of a layer containing cobalt can be effectively suppressed. Furthermore, an oxidizing agent has an effect of attaining a high polishing speed for a layer containing copper. Therefore, the polishing composition of the present invention can be used to suppress dissolution of a layer containing cobalt while maintaining a high polishing speed for a layer containing copper.

### [Object to be Polished]

First, the object to be polished according to the present invention and an example of a semiconductor wiring process will be explained. A semiconductor wiring process usually includes the following steps.

First, an insulator layer having trenches is formed on a substrate. Then, a barrier layer, a layer containing cobalt, and a layer containing copperas a metal wiring layer are formed sequentially on the insulator layer. The phrase “containing cobalt” as used herein is referred to as an embodiment in which elemental cobalt is contained in the layer, and the cobalt in the layer may be a simple substance, or may exist in the form of a cobalt oxide, a cobalt compound, a cobalt alloy or the like. Similarly, the phrase “containing copper” as used herein is referred to as an embodiment in which elemental copper is contained in the layer, and the copper in the layer may be a simple substance, or may exist in the form of a copper oxide, a copper compound, a copper alloy or the like.

The barrier layer and the layer containing cobalt are formed on the insulator layer so as to cover the surface of the insulator layer, before the layer containing copper (metal wiring layer) is formed. A method for forming the layers is not particularly limited, and for example, the layer can be formed by a known method such as a sputtering method or a plating method. Thicknesses of the barrier layer and the layer containing cobalt are smaller than a depth and width of trenches. The layer containing copper (metal wiring layer) is formed on the barrier layer such that at least the trenches are filled therewith, after the formation of the barrier layer and the layer containing cobalt. A method for forming a layer containing copper (metal wiring layer) is not particularly limited, and for example, the layer can be formed by a known method such as a sputtering method or a plating method.

Next, excess portions of the layer containing copper (metal wiring layer), the layer containing cobalt and the barrier layer, other than the wiring portion, are eliminated by CMP. As a result, at least a portion of the barrier layer located inside the trench (inner part of the barrier layer), at least a portion of the layer containing cobalt located inside the trench (inner part of the layer containing cobalt), and at least a portion of the layer containing copper (metal wiring layer) located inside the trench (inner part of the layer containing copper) remain on the insulator layer. That is, a portion of the barrier layer, a portion of the layer containing cobalt, and a portion of the layer containing copper remain inside each the trench. Thus, the portion of the layer containing copper that remains inside the trench functions as wiring.

Examples of the metal that is included in the barrier layer include tantalum, titanium, tungsten; and noble metals such as gold, silver, platinum, palladium, rhodium, ruthenium, iridium, and osmium. These other metals may be used singly or in combination of two or more kinds thereof.

The layer containing copper may also include a metal other than copper. Examples thereof include aluminum, hafnium, cobalt, nickel, titanium, and tungsten. These metals may also be included in the layer containing copper in the form of an alloy or a metal compound. These metals may be used singly, or in combination of two or more kinds thereof.

Next, the configuration of the polishing composition of the present invention will be described in detail.

### [Polishing Composition]

### (Oxidizing Agent)

The polishing composition according to the present invention includes an oxidizing agent. The oxidizing agent serves to attain a high polishing speed for a layer containing copper.

The oxidizing agent that can be used is, for example, a peroxide. Specific examples of the peroxide include, for example, hydrogen peroxide, peracetic acid, a percarbonic acid salt, urea peroxide; oxoacid salts of halogen elements, such as a perchlorate, a chlorate, a chlorite, and a hypochlorite; and persulfuric acid salts such as sodium persulfate, potassium persulfate, and ammonium persulfate. Among them, persulfuric acid salts and hydrogen peroxide are preferred from the viewpoint of the polishing speed, and hydrogen peroxide is particularly preferred from the viewpoints of stability in an aqueous solution and environmental burden.

A lower limit of a content of the oxidizing agent in the polishing composition is preferably 0.01% by mass or more, more preferably 0.05% by mass or more, and even more preferably 0.1% by mass or more. As the content of the oxidizing agent increases, a polishing speed for a layer containing copper can be further increased. An upper limit of a content of the oxidizing agent in the polishing composition is preferably 20% by mass or less, more preferably 15% by mass or less, and even more preferably 10% by mass or less. As the content of the oxidizing agent is smaller, a material cost for the polishing composition can be lowered, and in addition, there is an advantage that burden for treatment of the polishing composition after use in polishing, that is, burden for waste water treatment, can be reduced. Furthermore, there is also an advantage that excessive oxidation of a surface of an object to be polished caused by the oxidizing agent does not easily occur.

### (Cobalt Dissolution Inhibitor)

The polishing composition of the present invention includes a cobalt dissolution inhibitor. The cobalt dissolution inhibitor is added for the purpose of preventing cobalt from being dissolved when CMP is performed, as described above. According to the present invention, the cobalt dissolution inhibitor is at least one selected from the group consisting of a compound having a nitrogen-containing 5-membered ring structure, and a compound having two or more carboxyl groups.

### <Compound Having Nitrogen-Containing 5-Membered Ring Structure>

Examples of the compound having a nitrogen-containing 5-membered ring structure include a pyrrole compound, a pyrazole compound, an imidazole compound, a triazole compound, a tetrazole compound, an indolizine compound, an indole compound, an isoindole compound, an indazole compound, a purine compound, a thiazole compound, an isothiazole compound, an oxazole compound, an isoxazole compound, and a furazan compound.

More specific examples include, as examples of the pyrrole compound, 1H-pyrrole, 3-methylpyrrole, 3-hexylpyrrole, 3-phenylpyrrole, N-phenylpyrrole, N-ethylsulfonate pyrrole, 3,4-cyclohexylpyrrole, N-(4-fluorophenyl)pyrrole, N-(4-chlorophenyl)pyrrole, N-(4-cyanophenyl)pyrrole, N-(4-nitrophenyl)pyrrole, N-(4-aminophenyl)pyrrole, N-(4-methoxyphenyl)pyrrole, N-(4-(1-oxoethyl)phenyl)pyrrole, N-(4-trifluoromethylphenyl)pyrrole, N-(4-carbomethoxyphenyl)pyrrole, N-(4-carboxyphenyl)pyrrole, N-(1-naphthyl)pyrrole, and N-(2-naphthyl)pyrrole.

Examples of the pyrazole compound include, for example, 1H-pyrazole, 4-nitro-3-pyrazolecarboxylic acid, 3,5-pyrazolecarboxylic acid, 3-amino-5-phenylpyrazole, 5-amino-3-phenylpyrazole, 3,4,5-tribromopyrazole, 3-aminopyrazole, 3,5-dimethylpyrazole, 3,5-dimethyl-1-hydroxymethylpyrazole, 3-methylpyrazole, 1-methylpyrazole, 3-amino-5-methylpyrazole, 4-aminopyrazolo[3,4-d]pyrimidine, 1,2-dimethylpyrazole, 4-chloro-1H-pyrazolo[3,4-D]pyrimidine, 3,4-dihydroxy-6-methylpyrazolo(3,4-B)pyridine, and 6-methyl-1H-pyrazolo[3,4-b]pyridin-3-amine.

Examples of the imidazole compound include, for example, 1H-imidazole, 1-methylimidazole, 2-methylimidazole, 4-methylimidazole, 2-ethyl-4-methylimidazole, 2-isopropylimidazole, benzimidazole, 5,6-dimethylbenzimidazole, 2-aminobenzimidazole, 2-chlorobenzimidazole, 2-methylbenzimidazole, 2-(1-hydroxyethyl)benzimidazole, 2-hydroxybenzimidazole, 2-phenylbenzimidazole, 2,5-dimethylbenzimidazole, 5-methylbenzimidazole, and 5-nitrobenzimidazole.

Examples of the triazole compound include, for example, 1,2,3-triazole, 1,2,4-triazole, 1-methyl-1,2,4-triazole, methyl-1H-1,2,4-triazole-3-carboxylate, 1,2,4-triazole-3-carboxylic acid, methyl 1,2,4-triazole-3-carboxylate, 1H-1,2,4-triazole-3-thiol, 3,5-diamino-1H-1,2,4-triazole, 3-amino-1,2,4-triazole-5-thiol, 3-amino-1H-1,2,4-triazole, 3-amino-5-benzyl-4H-1,2,4-triazole, 3-amino-5-methyl-4H-1,2,4-triazole, 3-nitro-1,2,4-triazole, 3-bromo-5-nitro-1,2,4-triazole, 4-(1,2,4-triazol-1-yl)phenol, 4-amino-1,2,4-triazole, 4-amino-3,5-dipropyl-4H-1,2,4-triazole, 4-amino-3,5-dimethyl-4H-1,2,4-triazole, 4-amino-3,5-dipeptyl-4H-1,2,4-triazole, 5-methyl-1,2,4-triazole-3,4-diamine, 1H-benzotriazole, 1-hydroxybenzotriazole, 1-aminobenzotriazole, 1-carboxybenzotriazole, 5-chloro-1H-benzotriazole, 5-nitro-1H-benzotriazole, 5-carboxy-1H-benzotriazole, 5-methyl-1H-benzotriazole, 5,6-dimethyl-1H-benzotriazole, 1-(1′,2′-dicarboxyethyl)benzotriazole, 1-[N,N-bis(hydroxyethyl)aminomethyl]benzotriazole, 1-[N,N-bis(hydroxyethyl)aminomethyl]-5-methylbenzotriazole, and 1-[N,N-bis(hydroxyethyl)aminomethyl]-4-methylbenzotriazole.

Examples of the tetrazole compound include, for example, 1H-tetrazole, 5,5′-bis-1H-tetrazole, 5-methyl-1H-tetrazole, 5-phenyl-1H-tetrazole, 5-amino-1H-tetrazole, 5-mercapto-1H-tetrazole, 1-methyl-1H-tetrazole, 1-phenyl-1H-tetrazole, 1-amino-1H-tetrazole, 1-mercapto-1H-tetrazole, 1-phenyl-5-methyl-1H-tetrazole, 1-phenyl-5-amino-1H-tetrazole, and 1-phenyl-5-mercapto-1H-tetrazole.

Examples of the indolizine compound include, for example, indolizine.

Examples of the indole compound include, for example, 1H-indole, 1-methyl-1H-indole, 2-methyl-1H-indole, 3-methyl-1H-indole, 4-methyl-1H-indole, 5-methyl-1H-indole, 6-methyl-1H-indole, 7-methyl-1H-indole, 4-amino-1H-indole, 5-amino-1H-indole, 6-amino-1H-indole, 7-amino-1H-indole, 4-hydroxy-1H-indole, 5-hydroxy-1H-indole, 6-hydroxy-1H-indole, 7-hydroxy-1H-indole, 4-methoxy-1H-indole, 5-methoxy-1H-indole, 6-methoxy-1H-indole, 7-methoxy-1H-indole, 4-chloro-1H-indole, 5-chloro-1H-indole, 6-chloro-1H-indole, 7-chloro-1H-indole, 4-carboxy-1H-indole, 5-carboxy-1H-indole, 6-carboxy-1H-indole, 7-carboxy-1H-indole, 4-nitro-1H-indole, 5-nitro-1H-indole, 6-nitro-1H-indole, 7-nitro-1H-indole, 4-nitrile-1H-indole, 5-nitrile-1H-indole, 6-nitrile-1H-indole, 7-nitrile-1H-indole, 2,5-dimethyl-1H-indole, 1,2-dimethyl-1H-indole, 1,3-dimethyl-1H-indole, 2,3-dimethyl-1H-indole, 5-amino-2,3-dimethyl-1H-indole, 7-ethyl-1H-indole, 5-(aminomethyl)indole, 2-methyl-5-amino-1H-indole, 3-hydroxymethyl-1H-indole, 6-isopropyl-1H-indole, and 5-chloro-2-methyl-1H-indole.

Examples of the isoindole compound include, for example, 2H-isoindole.

Examples of the indazole compound include, for example, 1H-indazole, 5-amino-1H-indazole, 5-nitro-1H-indazole, 5-hydroxy-1H-indazole, 6-amino-1H-indazole, 6-nitro-1H-indazole, 6-hydroxy-1H-indazole, and 3-carboxy-5-methyl-1H-indazole.

Examples of the purine compound include, for example, purine. Examples of the thiazole compound include, for example, 1,3-thiazole. Examples of the isothiazole compound include, for example, 1,2-thiazole. Examples of the oxazole compound include, for example, 1,3-oxazole. Examples of the isoxazole compound include, for example, 1,2-oxazole. Examples of the furazan compound include, for example, 1,2,5-oxadiazole.

Among these, from the viewpoint of securing a high polishing speed for a layer containing copper, at least one selected from the group consisting of 1H-benzotriazole, 5-methyl-1H-benzotriazole, 1H-imidazole and 1H-tetrazole is preferred.

### <Aminocarboxylic Acid Having Two or More Carboxyl Groups>

Examples of an aminocarboxylic acid having two or more carboxyl groups include, for example, N,N′-bis(2-hydroxybenzyl)ethylenediamine-N,N′-diacetic acid, diethylenetriamine pentaacetic acid, triethylenetetramine-N,N,N″,N″,N′″,N′″-hexaacetic acid, nitrilotriacetic acid, N-(2-hydroxyethyl)iminodiacetic acid, N-(2-hydroxyethyl)ethylenediamine-N,N′,N′-triacetic acid, 1,2-diaminopropane-N,N,N′,N′-tetraacetic acid, 1,3-diaminopropane-N,N,N′,N′-tetraacetic acid, trans-cyclohexanediamine-N,N,N′,N′-tetraacetic acid, iminodiacetic acid, ethyl ether diaminetetraacetic acid, glycol ether diaminetetraacetic acid, ethylenediaminetetrapropionic acid, and phenylenediaminetetraacetic acid.

Among these, from the viewpoint of securing a high polishing speed for a layer containing copper, at least one selected from the group consisting of diethylenetriaminepentaacetic acid, triethylenetetramine-N,N,N″,N″,N′″,N′″-hexaacetic acid, nitrilotriacetic acid, N-(2-hydroxyethyl)iminodiacetic acid, and N-(2-hydroxyethyl)ethylenediamine-N,N′,N′-triacetic acid is preferred.

A lower limit of a content of the cobalt dissolution inhibitor in the polishing composition is preferably 0.001 mol/L or more, more preferably 0.005 mol/L or more, and even more preferably 0.01 mol/L or more. As the content of the cobalt dissolution inhibitor increases, dissolution of a layer containing cobalt can be further suppressed.

Furthermore, an upper limit of a content of the cobalt dissolution inhibitor in the polishing composition is preferably 100 mol/L or less, more preferably 50 mol/L or less, and even more preferably 10 mol/L or less. As the content of the cobalt dissolution inhibitor decreases, storage stability can be secured.

### [Other Components]

The polishing composition of the present invention may further include another component such as abrasive grains, a dispersing medium, a solvent, a pH adjusting agent, a polishing accelerator, a metal anticorrosive, a surfactant, an antiseptic agent, an antifungal agent, and a water-soluble polymer, as necessary. In the following description, the above-mentioned other components will be explained.

### (Abrasive Grains)

The polishing composition of the present invention preferably includes abrasive grains. The abrasive grains serve to mechanically polish an object to be polished, and increase a polishing speed by the polishing composition for an object to be polished.

The abrasive grains to be used may be any of inorganic particles, organic particles, and organic-inorganic composite particles. Specific examples of the inorganic particles include, for example, particles formed from metal oxides such as silica, alumina, ceria, and titania; silicon nitride particles, silicon carbide particles, and boron nitride particles. Specific examples of the organic particles include, for example, polymethyl methacrylate (PMMA) particles. The abrasive grains may be used singly or as mixtures of two or more kinds thereof. Also, the abrasive grains may be a commercially available product, or may be a synthesized product.

Among these abrasive grains, silica and alumina are preferred, and particularly preferred is colloidal silica.

### <Silica>

### <<Surface Modification>>

The abrasive grains may be subjected to surface modification. Since conventional colloidal silica has a zeta potential value close to zero under acidic conditions, silica particles do not electrically repel from each other and are likely to aggregate under acidic conditions. In contrast, abrasive grains to be surface-modified so as to have a relatively large negative value of zeta potential even under acidic conditions, strongly repel from each other and are satisfactorily dispersed even under acidic conditions. As a result, storage stability of the polishing composition can be enhanced. Such surface-modified abrasive grains can be obtained by, for example, mixing a metal such as aluminum, titanium and zirconium, or an oxide of such a metal, with abrasive grains, thereby doping the metal into the surface of the abrasive grains.

Anionic Sol

A particularly preferred example of the abrasive grains to be included in the polishing composition according to the present invention is colloidal silica having an organic acid immobilized thereto. Immobilization of an organic acid onto surface of colloidal silica included in a polishing composition may be achieved by, for example, chemically binding a functional group of the organic acid to the surface of the colloidal silica. Immobilization of an organic acid onto colloidal silica is not accomplished simply by incorporating colloidal silica and an organic acid together. If sulfonic acid, which is a kind of organic acid, is to be immobilized to colloidal silica, this can be carried out by, for example, the method described in “Sulfonic acid-functionalized silica through quantitative oxidation of thiol groups”, Chem. Commun., 246-247 (2003). Specifically, a colloidal silica having sulfonic acid immobilized on its surface can be obtained by coupling a silane coupling agent having a thiol group, such as 3-mercaptopropyltrimethoxysilane, the colloidal silica, and then oxidizing the thiol group with hydrogen peroxide. Alternatively, if a carboxylic acid is to be immobilized to colloidal silica, this can be carried out by, for example, the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, a colloidal silica having a carboxylic acid immobilized on its surface can be obtained by coupling a silane coupling agent containing a photoreactive 2-nitrobenzyl ester to the colloidal silica, and then irradiating the colloidal silica with light.

Cationic Sol

A cationic silica produced by adding a basic aluminum salt or a basic zirconium salt, as disclosed in JP 4-214022 A, can also be used as abrasive grains.

### <<Particle Size>>

Average Primary Particle Size

A lower limit of an average primary particle size of abrasive grains is preferably 3 nm or more, more preferably 5 nm or more, and even more preferably 7 nm or more. Furthermore, an upper limit of an average primary particle size of abrasive grains is preferably 200 nm or less, more preferably 150 nm or less, and even more preferably 100 nm or less.

When the average primary particle size is in such a range, a polishing speed by the polishing composition for an object to be polished can be increased, and dishing occurring on the surface of the object to be polished after being polished using the polishing composition can be further suppressed. The average primary particle size of the abrasive grains is calculated, for example, based on a specific surface area of abrasive grains as measured by the BET method.

Average Secondary Particle Size

A lower limit of an average secondary particle size of abrasive grains is preferably 10 nm or more, more preferably 15 nm or more, and even more preferably 20 nm or more. Furthermore, an upper limit of an average secondary particle size of abrasive grains is preferably 300 nm or less, more preferably 260 nm or less, and even more preferably 220 nm or less. When the average secondary particle size is in such a range, a polishing speed by the polishing composition for an object to be polished can be increased, and generation of surface defects on a surface of an object to be polished after being polished using the polishing composition can be further suppressed. The secondary particles as used herein refer to particles that are formed by association of abrasive grains in the polishing composition. The average secondary particle size of the abrasive grains can be measured by, for example, a dynamic light scattering method.

### <<Concentration>>

A lower limit of a content of abrasive grains in the polishing composition of the present invention is preferably 0.005% by mass or more, more preferably 0.01% by mass or more, and even more preferably 0.1% by mass or more from the viewpoint of improving a polishing speed of an object to be polished. Furthermore, an upper limit of a content of abrasive grains in the polishing composition is preferably 50% by mass or less, more preferably 30% by mass or less, and even more preferably 20% by mass or less, from the viewpoints of reducing cost of the polishing composition and suppressing occurrence of surface defects on a surface of An object to be polished after being polished.

### (Dispersing Medium or Solvent)

The polishing composition of the present invention is usually contains a dispersing medium or a solvent for dispersing or dissolving each component. Regarding the dispersing medium or solvent, an organic solvent, water and the like may be considered. Among them, the polishing composition preferably includes water. Water that does not contain impurities as far as possible is preferred, from the viewpoint that the impurities may inhibit the action by other components. Specifically, pure water and ultrapure water from which impurity ions have been removed using an ion exchange resin and then foreign materials have been removed through a filter, or distilled water is preferred.

### (pH Adjusting Agent)

A pH of the polishing composition according to the present invention can be adjusted by adding an appropriate amount of a pH adjusting agent thereto as necessary. The pH adjusting agent may be any of an acid or an alkali, and may be anyone of inorganic and organic compounds. Thereby, a polishing speed for an object to be polished, dispersibility of the abrasive grains, and the like can be controlled. The pH adjusting agent may be used singly, or two or more kinds thereof may be used as mixtures.

Regarding the pH adjusting agent, a known acid, a known base, or a salt thereof can be used. Specific examples of the acid include, for example, inorganic acids such as sulfuric acid, nitric acid, boric acid, carbonic acid, hypophosphorous acid, phosphorous acid, and phosphoric acid; and organic acids including carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, and organic sulfuric acids such as methanesulfonic acid, ethanesulfonic acid, and isethionic acid.

Specific examples of the base that can be used as a pH adjusting agent include hydroxides of alkali metals or salts thereof, hydroxides of Group 2 elements or salts thereof, quaternary ammonium hydroxides or salts thereof, ammonia, and amines. Specific examples of the alkali metals include potassium and sodium. Specific examples of the salts include a carbonate, a hydrogen carbonate, a sulfate, and an acetate. Specific examples of quaternary ammoniums include tetramethylammonium, tetraethylammonium, and tetrabutylammonium.

Quaternary ammonium hydroxide compounds include quaternary ammonium hydroxide or salts thereof, and specific examples thereof include tetramethylammonium hydroxide, tetraethylammonium hydroxide, and tetrabutylammonium hydroxide.

Specific examples of the amines include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, piperazine anhydride, piperazine hexahydrate, 1-(2-aminoethyl)piperazine, N-methylpiperazine, and guanidine. These bases may be used singly, or two or more kinds thereof may be used in combination.

Among these bases, ammonia, an ammonium salt, an alkali metal hydroxide, an alkali metal salt, a quaternary ammonium hydroxide compound, and an amine are preferred. More preferably, ammonia, a potassium compound, sodium hydroxide, a quaternary ammonium hydroxide compound, ammonium hydrogen carbonate, ammonium carbonate, sodium hydrogen carbonate, and sodium carbonate are applicable. Furthermore, the polishing composition more preferably includes a potassium compound as a base, from the viewpoint of preventing metal contamination. Examples of the potassium compound include hydroxide or salts of potassium, and specific examples include potassium hydroxide, potassium carbonate, potassium hydrogen carbonate, potassium sulfate, potassium acetate, and potassium chloride.

An amount of the pH adjusting agent to be added is not particularly limited, and the amount may be appropriately adjusted so that the polishing composition acquires a desired pH value.

Regarding a lower limit of pH range for the polishing composition of the present invention, from the viewpoint that as a pH becomes higher, dissolution of an object to be polished proceeds, and a polishing speed by the polishing composition increases, the lower limit is preferably 3 or higher, more preferably 4 or higher, and even more preferably 5 or higher. Furthermore, an upper limit of pH range is preferably below 14, from the viewpoint that as the pH becomes lower, handling is made easier.

### (Polishing Accelerator)

The polishing composition of the present invention preferably includes a polishing accelerator. The polishing accelerator serves to chemically etch a surface of an object to be polished, and to increase a polishing speed by the polishing composition for an object to be polished.

Examples of the polishing accelerator include an inorganic acid or a salt thereof, an organic acid or a salt thereof, a nitrile compound, an amino acid, and a chelating agent. These polishing accelerators may be used singly, or two or more kinds thereof may be used as mixtures. Furthermore, regarding the polishing accelerator, a commercially available product may be used, or a synthesized product may be used.

Specific examples of the inorganic acid include sulfuric acid, nitric acid, carbonic acid, boric acid, tetrafluoroboric acid, hypophosphorous acid, phosphorous acid, phosphoric acid, and pyrophosphoric acid.

Specific examples of the organic acid include, for example, monovalent carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, lactic acid, glycolic acid, glyceric acid, benzoic acid, and salicylic acid. Furthermore, sulfonic acids such as methanesulfonic acid, ethanesulfonic acid and isethionic acid can also be used.

As the polishing accelerator, a salt of the aforementioned inorganic acid or the aforementioned organic acid may also be used. Particularly, in the case of using a salt of weak acid and strong base, a salt of strong acid and weak base, or a salt of weak acid and weak base, a pH buffering effect can be expected. Examples of such a salt include, for example, potassium chloride, sodium sulfate, potassium nitrate, potassium carbonate, potassium tetrafluoroborate, potassium pyrophosphate, potassium oxalate, trisodium citrate, potassium (+)-tartrate, and potassium hexafluorophosphate.

Specific examples of the nitrile compound include, for example, acetonitrile, aminoacetonitrile, propionitrile, butyronitrile, isobutyronitrile, benzonitrile, glutaronitrile, and methoxyacetonitrile.

Specific examples of the amino acid include glycine, α-alanine, β-alanine, N-methylglycine, N,N-dimethylglycine, 2-aminobutyric acid, norvaline, valine, leucine, norleucine, isoleucine, phenylalanine, proline, sarcosine, ornithine, lysine, taurine, serine, threonine, homoserine, tyrosine, bicine, tricine, 3,5-diiodotyrosine, β-(3,4-dihydroxyphenyl)-alanine, thyroxine, 4-hydroxyproline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, δ-hydroxylysine, creatine, histidine, 1-methylhistidine, 3-methylhistidine, and tryptophan.

Specific examples of the chelating agent include N,N,N-trimethylenephosphonic acid, ethylenediamine-N,N,N′,N′-tetramethylenesulfonic acid, 2-phosphonobutane-1,2,4-tricarboxylic acid, 1-hydroxyethylidene-1,1-diphosphonic acid, and 1,2-dihydroxybenzene-4,6-disulfonic acid.

Among these, at least one selected from the group consisting of organic acids or salts thereof, carboxylic acids or salt thereof, and nitrile compounds is preferred, and from the viewpoint of stability of a complex structure with a metal compound included in an object to be polished, inorganic acids or salt thereof are more preferred. Furthermore, when a compound having a pH adjusting function (for example, various acids) is used as the polishing accelerator as mentioned above, the polishing accelerator may be utilized as at least a part of a pH adjusting agent.

A lower limit of a content (concentration) of the polishing accelerator in the polishing composition is not particularly limited since even a small amount of the polishing accelerator can exhibit effects. The content is preferably 0.001 g/L or more, more preferably 0.01 g/L or more, and even more preferably 1 g/L or more. As the content becomes larger, a polishing speed can be further increased. Furthermore, an upper limit of a content (concentration) of the polishing accelerator in the polishing composition is preferably 200 g/L or less, more preferably 150 g/L or less, and even more preferably 100 g/L or less. As the content becomes smaller, dissolution of cobalt can be prevented, and a level difference elimination performance can be enhanced.

### (Metal Anticorrosive)

The polishing composition of the present invention may also include a metal anticorrosive. The incorporation of a metal anticorrosive to the polishing composition can suppress dissolution of a metal, particularly dissolution of a layer containing copper, thereby suppressing deterioration of a surface state such as surface roughness of a polished surface.

The metal anticorrosive that can be used is not particularly limited. The metal anticorrosive is preferably a heterocyclic compound. The heterocyclic compound may be a monocyclic compound, or may be a polycyclic compound having a fused ring. The metal anticorrosive may be used singly or as a mixture of two or more kinds thereof. Furthermore, regarding the metal anticorrosive, a commercially available product may be used, or a synthesized product may be used.

Examples of the heterocyclic compound that can be used as the metal anticorrosive include nitrogen-containing heterocyclic compounds such as a pyridine compound, a pyrazine compound, a pyridazine compound, a pyrindine compound, a quinolidine compound, a quinoline compound, an isoquinoline compound, a naphthyridine compound, a phthalazine compound, a quinoxaline compound, a quinazoline compound, a cinnoline compound, a pteridine compound, and a furazan compound.

A lower limit of a content of the metal anticorrosive in the polishing composition is preferably 0.001 g/L or more, more preferably 0.005 g/L or more, and even more preferably 0.01 g/L or more. As the content of the metal anticorrosive becomes larger, dissolution of metal can be prevented, and a level difference elimination performance can be enhanced. Furthermore, an upper limit of a content of the metal anticorrosive in the polishing composition is preferably 10 g/L or less, more preferably 5 g/L or less, and even more preferably 2 g/L or less. As the content of the metal anticorrosive becomes smaller, the polishing speed can be increased.

### (Surfactant)

The polishing composition of the present invention preferably includes a surfactant. The surfactant can suppress dishing that may occur on a polished surface after polishing. The surfactant may be any of an anionic surfactant, a cationic surfactant, an amphoteric surfactant, and a nonionic surfactant.

Specific examples of the anionic surfactant include a polyoxyethylene alkyl ether acetic acid, a polyoxyethylene alkyl sulfuric acid ester, an alkyl sulfuric acid ester, a polyoxyethylene alkyl sulfuric acid, an alkyl sulfuric acid, an alkyl benzenesulfonic acid, an alkyl phosphoric acid ester, a polyoxyethylene alkyl phosphoric acid ester, a polyoxyethylene sulfosuccinic acid, an alkyl sulfosuccinic acid, an alkyl naphthalenesulfonic acid, an alkyl diphenyl ether disulfonic acid, and salts thereof.

Specific examples of the cationic surfactant include an alkyltrimethylammonium salt, an alkyldimethylammonium salt, an alkylbenzyldimethylammonium salt, and an alkylamine salt.

Specific examples of the amphoteric surfactant include an alkylbetaine and an alkylamine oxide. Specific examples of the nonionic surfactant include a polyoxyalkylene alkyl ether such as a polyoxyethylene alkyl ether, a sorbitan fatty acid ester, a glycerin fatty acid ester, a polyoxyethylene fatty acid ester, a polyoxyethylene alkylamine, and an alkylalkanol amide. These surfactants may be used singly, or two or more kinds thereof may be used in combination.

Furthermore, as the surfactant, a surfactant represented the following Formula (1) may be also advantageously used.

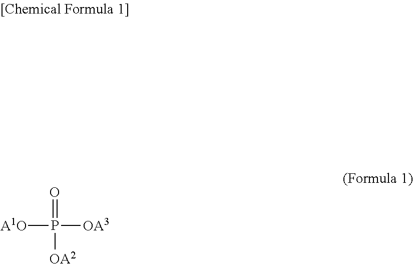

wherein in the Formula (1), A¹ to A³ each independently represent a hydrogen atom, a methyl group, an ethyl group, or a polyoxyalkylene aryl ether group, provided that at least one of A¹ to A³ represents a polyoxyalkylene aryl ether group, and the polyoxyalkylene aryl ether group is a compound represented by the following formula, or salt thereof:

[Chemical Formula 2]

O-EₙO—Ar (Formula 2)

wherein in the Formula (2), Ar represents an aryl group having 6 to 20 carbon atoms which may have a substituent, E represents an alkylene group having 1 to 3 carbon atoms and n is 1 to 100,

The surfactant represented by the Formula (1) contains a phosphoric acid skeleton, and has chelating effects for metal wiring (for example, copper, or a copper alloy). If a polyoxyalkylene aryl ether group exists, the chelating ability is deteriorated to be regulated to an appropriate level. As a result, dishing of a metal wiring can be prevented while a polishing rate for metal wiring is exhibited.

In the Formula (1), A¹ to A³ each independently represent a hydrogen atom, a methyl group, an ethyl group, or a polyoxyalkylene aryl ether group, provided that at least one of A¹ to A³ represents a polyoxyalkylene aryl ether group. However, from the viewpoint of suppressing etching of a metal surface, it is preferable that one of A¹ to A³ is a polyoxyalkylene aryl ether group. Furthermore, from the viewpoint of dispersibility of a surfactant in the polishing composition, it is preferable that at least one of A¹ to A³ represents a hydrogen atom. Also, from the viewpoint that a low level difference can be attained while maintaining a high polishing speed, it is preferable that one of A¹ to A³ is a polyoxyalkylene aryl ether group in which Ar is represented by the following Formula (3), and the others are a hydrogen atom. One kind of the compound of the Formula (1) may be used, or two or more kinds of the compound of the Formula (1) may also be used. Furthermore, a monoester, a diester, and a triester may be used in combination.

The surfactant represented by the Formula (1) may be in the form of a salt. Specific examples of the salt include a monovalent or divalent metal salt, an ammonium salt, and an amine salt. Examples of the monovalent or divalent metal salt include a lithium salt, a sodium salt, a potassium salt, a magnesium salt, and a calcium salt. Among them, from the viewpoint of metal impurities of a polishing composition for semiconductor, the surfactant is preferably an amine salt or a potassium salt. Here, specific examples of the amine salt include triethanolamine and trimethanolamine. From the viewpoint of polishing performance, triethanolamine is suitable. Meanwhile, the term form of a salt refers to a form in which, when one or a plurality of A¹ to A³ is represents a hydrogen atom, some or all of the hydrogen atoms have been substituted with the salts listed above.

The polyoxyalkylene aryl ether group is represented by the following formula:

[Chemical Formula 3]

O-EₙO—Ar (Formula 2)

wherein in the Formula (2), Ar represents an aryl group having 6 to 20 carbon atoms which may have a substituent; E represents an alkylene group having 1 to 3 carbon atoms; and n is 1 to 100.

Here, regarding the number of carbon atoms in the aryl group for “Ar”, the aryl group has 6 to 20 carbon atoms; however, the aryl group preferably has 6 to 15 carbon atoms, more preferably 6 to 13 carbon atoms, and even more preferably 6 to 8 carbon atoms. When the number of carbon atoms is in such a range, desired effects by the present invention can be efficiently provided. Furthermore, there are no particular limitations on the specific examples of “Ar”, and examples include a phenyl group, a naphthyl group, and an anthracenyl group. However, particularly when a phenyl group is employed, desired effects by the present invention can be efficiently provided.

In view of the above description, Ar is represented by the following Formula (3):

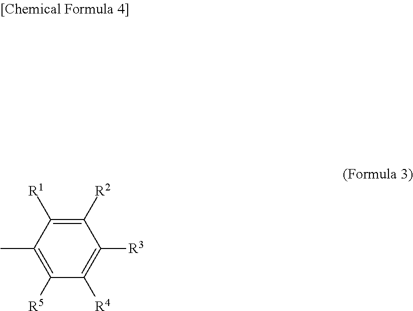

wherein in the Formula (3), R¹ to R⁵ each independently represent a hydrogen atom, a substituted or unsubstituted alkyl group having 1 to 21 carbon atoms, or a substituted or unsubstituted aryl group having 6 to 20 carbon atoms.

The number of carbon atoms of the alkyl group for the substituted or unsubstituted alkyl group having 1 to 21 carbon atoms is more preferably 1 to 18, more preferably 1 to 10, even more preferably 1 to 5, and particularly preferably 1 to 3, from the viewpoint of dispersion stability. There are no particular limitations on the specific examples of the alkyl group, and the alkyl group may be linear or branched. Examples thereof include a methyl group, an ethyl group, a propyl group, an isopropyl group, a butyl group, an isobutyl group, a sec-butyl group, a tert-butyl group, a pentyl group, an isopentyl group, a tert-pentyl group, a neopentyl group, a hexyl group, an isohexyl group, a heptyl group, an octyl group, a nonyl group, a decyl group, an undecyl group, a dodecyl group, a 2-ethylhexyl group, a tridecyl group, a tetradecyl group, a pentadecyl group, a hexadecyl group, a heptadecyl group, and an octadecyl group. Among them, a methyl group, an ethyl group, a propyl group, an isopropyl group, a butyl group, an isobutyl group, a sec-butyl group, and a tert-butyl group are preferred, and the alkyl group is more preferably a methyl group, an ethyl group, a propyl group, or an isopropyl group, and particularly preferably a methyl group or an ethyl group.

Furthermore, the substituent for the substituted or unsubstituted alkyl group having 1 to 21 carbon atoms is preferably an aryl group or a halogen atom. The aryl group is preferably a phenyl group, a naphthyl group or the like. The halogen atom is suitably chlorine, bromine, iodine or the like. Particularly, if the alkyl group has an aryl group as a substituent, when the surfactant adsorbs to a Cu surface, the Cu surface would become water-repellent, and it would become difficult for abrasive grains or a complexing agent to wet the Cu surface. Therefore, excessive polishing after exposure of a barrier film can be prevented.

The number of substituted alkyl groups for R¹ to R⁵ is preferably an integer from 1 to 3, from the viewpoint of dispersion stability. Furthermore, the site of alkyl group to be substituted for R¹ to R⁵ is also not particularly limited. From the viewpoint of realizing a low level difference with a high polishing speed, and suppressing etching, when the number is 1, the substitution is preferably at 3-position, and when the number is 3, substitutions are preferably at 2-position, 4-position, and 6-position.

The aryl group is a functional group or substituent derived from an aromatic hydrocarbon. The aryl group has 6 to 20 carbon atoms. From the viewpoint of dispersion stability, the aryl group preferably has 6 to 14 carbon atoms, and more preferably has 6 to 8 carbon atoms. There are no particular limitations on the specific examples of such an aryl group, and examples include a phenyl group, a naphthyl group, and an anthracenyl group. Furthermore, the substituent for the substituted or unsubstituted aryl group having 6 to 20 carbon atoms is suitably an alkyl group having 1 to 21 carbon atoms, a halogen atom, or the like. Regarding the examples of the alkyl group having 1 to 21 carbon atoms, the above-described examples are similarly adequate.

In view of the above description, regarding specific examples of Ar, those represented by the following formulae are suitably used:

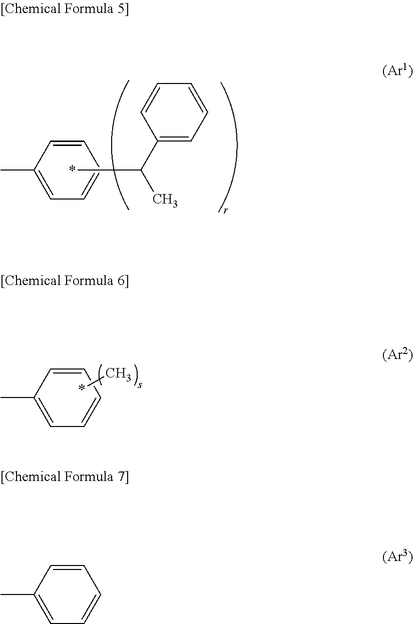

In Ar¹, r is an integer from 1 to 5, and from the viewpoint of dispersion stability, r is more preferably an integer from 1 to 3. In Ar², s is an integer from 1 to 5, and from the viewpoint of dispersion stability, s is more preferably an integer from 1 to 3, still more preferably an integer from 1 to 2, and particularly preferably 1. There are no particular limitations on the position of substitution of the phenyl group-substituted ethyl group in Ar¹; however, when r is 1, 3-position or 4-position are is preferable, and when r is 3, 2-position, 4-position and 6-position are preferable, from the viewpoint of attaining a high polishing speed and a low level difference and obtaining an effect of suppressing etching. Furthermore, when s is 1, 2-position, 3-position or 4-position is preferable, and from the viewpoint of obtaining an effect of suppressing etching, 3-position is particularly preferable.

Further, there are also no particularly limitations on the specific examples of the alkylene group having 1 to 3 carbon atoms for “E” in Formula (2), and the alkylene group may be linear or branched. Examples of the alkylene group include a methylene group, an ethylene group, a trimethylene group, and a propylene group. Particularly, if the alkylene group is an ethylene group, the desired effects by the present invention described above can be efficiently provided. Furthermore, n is from 1 to 100. From the viewpoint of dispersion stability, n is preferably an integer from 4 to 80, and more preferably an integer from 8 to 50.

In view of the above description, from the viewpoint of efficiently providing the desired effects of the present invention, compounds represented by the following Formulae (4) to (6) or salts thereof are suitably used as a surfactant.

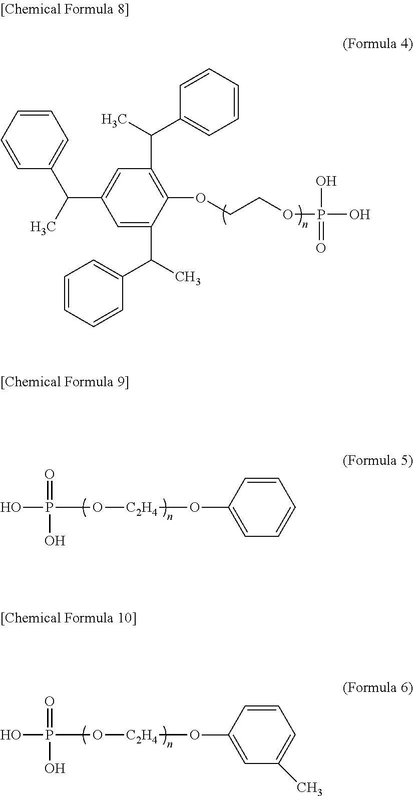

Particularly, in the case of attempting to enhance storage stability, a compound represented by Formula (6) or a salt thereof is suitable as a surfactant in terms of dispersion stability. In terms of balance between storage stability and polishing performance, a compound represented by Formula (4) or a salt thereof is suitable as a surfactant. As such, when a phenyl group-substituted ethyl group or an alkyl group is introduced into a phenyl group (a phenylether group), a high polishing speed and a superior etching suppressive effect can be efficiently provided.

A number average molecular weight (Mn) of the surfactant having a polyoxyalkylene aryl ether group is preferably in the range of 200 to 100,000, and more preferably in the range of 300 to 5,000. In the present invention, in regard to the number average molecular weight (Mn), a value measured by GPC (gel permeation chromatography) and calculated relative to polystyrene standards is employed.

As long as the surfactant represented by Formula (1) has a polyoxyalkylene aryl ether group, a commercially available product may be purchased, and if necessary, the surfactant may also be synthesized by making reference to conventionally known findings or by blending.

A lower limit of a content of the surfactant in the polishing composition is preferably 0.0001 g/L or more, and more preferably 0.001 g/L or more. As the content of the surfactant becomes larger, dishing after polishing can be further reduced. Furthermore, an upper limit of a content of the surfactant in the polishing composition is preferably 20 g/L or less, and more preferably 10 g/L or less. As the content of the surfactant becomes smaller, a decrease in the polishing speed can be suppressed.

### (Antiseptic Agent and Antifungal Agent)

Examples of an antiseptic agent and an antifungal agent that can be added to the polishing composition according to the present invention include isothiazoline-based antiseptic agents such as 2-methyl-4-isothiazolin-3-one and 5-chloro-2-methyl-4-isothiazolin-3-one; paraoxybenzoic acid esters; and phenoxyethanol. These antiseptic agents and antifungal agents may be used singly or as mixtures of two or more kinds thereof.

### (Water-Soluble Polymer or Salt Thereof)

The polishing composition according to the present invention may include a water-soluble polymer or a salt thereof. By adding a water-soluble polymer or a salt thereof, dispersion stability of the polishing composition can be enhanced, and through uniformization of a slurry concentration, stabilization of supplying the polishing composition can be attained. Also, surface roughness of an object to be polished after being polished using the polishing composition can be further reduced.

Specific examples of the water-soluble polymer include, for example, a polystyrene sulfonic acid salt, a polyisoprene sulfonic acid salt, a polyacrylic acid salt, polymaleic acid, polyitaconic acid, polyvinyl acetate, polyvinyl alcohol, polyglycerin, polyvinylpyrrolidone, a copolymer of isoprenesulfonic acid and acrylic acid, a polyvinylpyrrolidone-polyacrylic acid copolymer, a polyvinylpyrrolidone-vinyl acetate copolymer, a salt of naphthalenesulfonic acid-formalin condensate, a diallylamine hydrochloride-sulfur dioxide copolymer, carboxymethyl cellulose, a salt of carboxymethyl cellulose, hydroxyethyl cellulose, hydroxypropyl cellulose, pullulan, chitosan, and chitosan salts. These water-soluble polymers may be used singly or in combination of two or more kinds thereof.

A lower limit of a content of the water-soluble polymer or a salt thereof in the polishing composition is preferably 0.0001 g/L or more, and more preferably 0.001 g/L or more. As the content of the water-soluble polymer or a salt thereof becomes larger, surface roughness of a polished surface by the polishing composition can be further reduced. Also, an upper limit of a content of the water-soluble polymer or a salt thereof in the polishing composition is preferably 10 g/L or less, and more preferably 1 g/L or less. As the content of the water-soluble polymer or a salt thereof becomes smaller, a residual amount of the water-soluble polymer or a salt thereof on a polished surface can be reduced, and cleaning efficiency can be further increased.

### [Method for Producing Polishing Composition]

A method for producing the polishing composition of the present invention is not particularly limited, and for example, a polishing composition can be obtained by mixing with stirring an oxidizing agent, a cobalt dissolution inhibitor, and optionally another component(s) in a dispersing medium or a solvent, such as water.

A temperature in the mixing of various components is not particularly limited; however, the temperature is preferably 10 to 40° C., and the mixture may also be heated in order to increase a dissolution rate. A mixing time is also not particularly limited.

### [Polishing Method]

As described above, the polishing composition of the present invention can be suitably used for polishing an object to be polished having a layer containing copper and a layer containing cobalt. Therefore, the present invention is to provide a polishing method of polishing an object to be polished having a layer containing copper and a layer containing cobalt using the polishing composition of the present invention. In order to obtain the effects by the present invention more efficiently, it is preferable to polish the layer containing copper and the layer containing cobalt simultaneously. Furthermore, the present invention is to provide a method for producing a substrate, the method including a step of polishing an object to be polished having a layer containing copper and a layer containing cobalt by the polishing method described above.

Regarding a polishing apparatus, a general polishing apparatus which is equipped with a holder for retaining a substrate or the like having an object to be polished, and a motor or the like capable of varying the number of rotation, and has a polishing table to which a polishing pad (polishing cloth) can be attached, can be used.

Regarding the polishing pad, a nonwoven fabric, a polyurethane polishing pad, a porous fluororesin and the like can be used without particular limitations. It is preferable that the polishing pad is subjected to grooving for the retention of polishing liquid.

There are no particular limitations on polishing conditions, and for example, a rotation speed of the polishing table is preferably 10 to 500 rpm, and a pressure applied to an object to be polished (polishing pressure) is preferably 0.1 to 10 psi. A method for supplying the polishing composition to the polishing pad is also not particularly limited, and for example, a method of continuously supplying the polishing composition with a pump or the like can be employed. Although a supply amount of the polishing composition is not limited, it is preferably such that a surface of the polishing pad is always covered with the polishing composition of the present invention.

After completion of polishing, the object to be polished is washed with flowing water, and is dried by dropping the water droplets adhering onto the object to be polished by means of a spin drier or the like. Thereby, an object to be polished which has been polished can be obtained.

### Examples

The present invention will be explained in more detail using the following Examples and Comparative Examples. However, the technical scope of the present invention is not intended to be limited to the following Examples only.

### [Etching Test]

30 g/L of aqueous hydrogen peroxide (concentration: 31% by mass) (9.3 g/L in terms of hydrogen peroxide in the polishing composition) as an oxidizing agent, 0.1 mol/L of a compound indicated in the following Table 1 as a cobalt dissolution inhibitor, and 10 g/L of glycine as a polishing accelerator were mixed with stirring in water (mixing temperature: about 25° C., mixing time: about 10 minutes), to prepare a polishing composition.

An etching test is performed by immersing a cobalt wafer processed into a size of 30 mm on each of four sides in a polishing composition contained in a 500-ml beaker for 3 minutes while being rotated at 300 rpm. A value obtained by dividing a difference between thicknesses of the coupon measured before and after immersion by the immersion time was designated as an etching rate for a layer containing cobalt. The results are presented in the following Table 1.

TABLE 1

| | | | Etching |
|---|---|---|---|
| | | | rate |
| | Type | Cobalt dissolution inhibitor | (Å/min) |
| Comparative | | None | 108 |
| Example 1 | | | |
| Comparative | | Triethylenetetramine | 64 |
| Example 2 | | | |
| Comparative | | 1,10-Phenanthroline hydrate | 76 |
| Example 3 | | | |
| Comparative | | Acetic acid | 122 |
| Example 4 | | | |
| Comparative | | Succinic acid | 50 |
| Example 5 | | | |
| Comparative | | Polyvinyl alcohol 1000 | 91 |
| Example 6 | | | |
| Comparative | | Polyvinylpyrrolidone K-15 | 104 |
| Example 7 | | | |
| Comparative | | Polyvinylpyrrolidone K-30 | 99 |
| Example 8 | | | |
| Comparative | | Polyethylene glycol 200 | 101 |
| Example 9 | | | |
| Comparative | | Polyethylene glycol 400 | 76 |
| Example 10 | | | |
| Comparative | | Ethylenediamine | 83 |
| Example 11 | | | |
| Example 1 | Aminocarboxylic | Diethylenetriaminepenta- | 5 |
| | acid | acetic acid | |
| Example 2 | | Triethylenetetramine- | 14 |
| | | N,N,N″,N″,N′″, | |
| | | N′″-hexaacetic acid | |
| Example 3 | | Nitrilotriacetic acid | 12 |
| Example 4 | | N-(2-hydroxyetyl)imino | 8 |
| | | diacetic acid | |
| Example 5 | | N-(2-hydroxyethyl) | 6 |
| | | ethylenediamine-N,N′,N′- | |
| | | triacetic acid | |
| Example 6 | Compound | 1H-benzotriazole | 4 |
| | having | | |
| | nitrogen- | | |
| | containing | | |
| | 5-membered | | |
| | ring structure | | |
| Example 7 | | 5-Methyl-1H-benzotriazole | 3 |
| Example 8 | | 1H-imidazole | 28 |
| Example 9 | | 1H-tetrazole | 7 |

As clearly noted from Table 1, the etching rates for a layer containing cobalt of the polishing compositions of Examples 1 to 9 were significantly lower than the etching rates for a layer containing cobalt of the polishing compositions of Comparative Examples 1 to 11.

### (Polishing Speed)

3 g/L of colloidal silica (average primary particle size: 10 nm, average secondary particle size: 28 nm) as abrasive grains, 10 g/L of hydrogen peroxide as an oxidizing agent, 0.5 g/L of polyoxyethylene alkyl ether as a surfactant, and 0.2 g/L of tristyryl phenyl ether EO phosphoric acid ester represented by Formula (4) (manufactured by Rhodia Nicca, Ltd., SOPROPHOR (registered trademark) 3D33), 0.1 mol/L of a cobalt dissolution inhibitor indicated in the following Table 3, and 10 g/L of glycine as a polishing accelerator were mixed with stirring in water (mixing temperature: about 25° C., mixing time: about 10 minutes). Furthermore, potassium hydroxide was used as a pH adjusting agent to adjust the pH to 7.0, to obtain a polishing composition. The pH of the polishing composition thus obtained was checked at 25° C. using a pH meter.

A cobalt/copper patterning wafer (having a Ta layer as a barrier layer) was polished using each of polishing compositions (Examples 10 to 13 and Comparative Example 12), under the polishing conditions indicated in the following Table 2.

TABLE 2
Polishing apparatus: CMP single-sided polishing apparatus for 300 mm
Pad: Polyurethane pad
Number of rotations of platen (polishing table): 80 rpm
Polishing pressure: 120 hPa (1.74 psi)
Flow rate of polishing composition: 200 ml/min
Polishing time: 60 seconds

A polishing speed was determined by dividing a respective difference of a thickness of a layer containing copper and a layer containing cobalt in a cobalt/copper patterning wafer measured before and after polishing using a sheet resistance analyzer based on the principle of a direct current four-probe method, by a polishing time. The results are shown in the following Table 3.

### (Topography)

A substrate (cobalt/copper patterning wafer having a barrier layer) having a line-and-space (L/S) pattern of various sizes was polished under the polishing conditions described in Table 2 until the barrier layer was exposed, and topography of a surface of a layer containing cobalt was analyzed by atomic force microscopy (AFM).

### (Recesses in Layer Containing Cobalt)

Cross-sections of patterns obtained after polishing a cobalt/copper patterning wafer using the polishing compositions of Examples 10 to 13 and Comparative Example 12, were observed by scanning electron microscopy.

The results for polishing speed, topography, and observation for recess in the layer containing cobalt are shown in the following Table 3.

TABLE 3

| | | Polishing speed | | | | | | |
|---|---|---|---|---|---|---|---|---|
| | | (Å/min) | | Topography | | | | |
| | | Layer | Layer | (Å) | | | | Recess in |
| | | containing | containing | L/S | L/S | L/S | L/S | layer |
| | Cobalt dissolution inhibitor | Cu | Co | 100 um | 50 um | 10 um | 0.18 um | containing Co |
| Comparative | None | 7479 | 4800 | 1500 | 1100 | 680 | 350 | Present |
| Example 12 | | | | | | | | |
| Example 10 | Diethylenetriaminepentaacetic acid | 6600 | 2183 | 761 | 666 | 320 | 45 | Absent |
| Example 11 | Triethylenetetramine-N,N,N″,N″,N′″,N′″- | 6824 | 2403 | 777 | 682 | 447 | 51 | Absent |
| | hexaacetic acid | | | | | | | |
| Example 12 | 1H-benzotriazole | 5542 | 1980 | 721 | 583 | 489 | 44 | Absent |
| Example 13 | 5-Methyl-1H-benzotriazole | 4800 | 1888 | 680 | 555 | 321 | 38 | Absent |

As clearly noted from Table 3, it was found that in the case of using the polishing compositions of Examples 10 to 13, a polishing speed for the layer containing copper was high, and a polishing speed for the layer containing cobalt was low. It was also found that a level difference in a layer containing cobalt was suppressed.

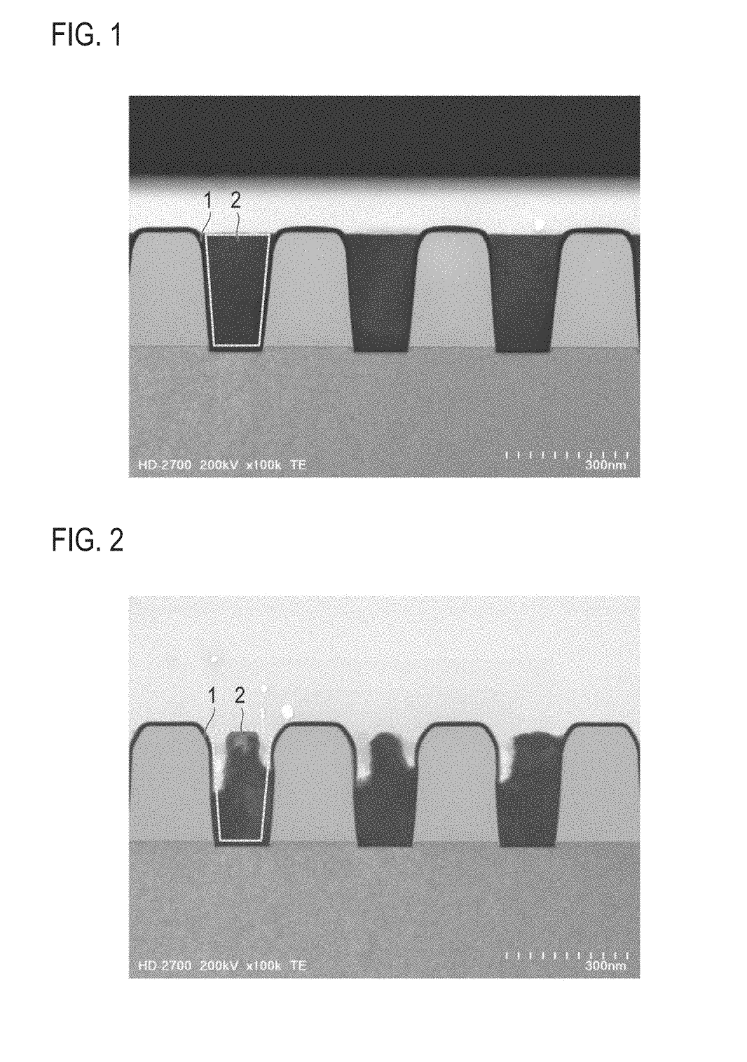

Although no recesses in the layer containing cobalt were observed when the polishing compositions of Examples 10 to 13 were used, recesses in the layer containing cobalt were observed when the polishing composition of Comparative Example 12 was used. FIG. 1 is a SEM (scanning electron microscopic) photograph showing a cross-section of the pattern after a cobalt/copper patterning wafer was polished using the polishing composition of Example 10, and FIG. 2 is the same SEM photography obtained using the polishing composition of Comparative Example 12. Furthermore, in FIG. 1 and FIG. 2, black-colored Part 1 represents a barrier layer (Ta layer), and Part 2 surrounded by dotted lines represents a layer containing copper. A layer containing cobalt is present at the interface between the Part 1 and the Part 2. In FIG. 1, almost no dissolution of the layer containing copper (Part 2) and the layer containing cobalt (interface between Part 1 and Part 2) is observed, while in FIG. 2, since dissolution occurred starting from the layer containing cobalt which existed at the interface between Part 2 and Part 1, it is understood that dissolution of the layer containing copper (Part 2) that is adjacent to the layer containing cobalt at the interface between Part 2 and Part 1 had also proceeded.

The present patent application is based on JP 2014-182583 filed on Sep. 8, 2014, the entire disclosure of which is incorporated herein by reference.

1.-9. (canceled)

10. A polishing composition used for polishing an object to be polished having a layer containing copper and a layer containing cobalt, the polishing composition comprising:
an oxidizing agent; and
at least one cobalt dissolution inhibitor selected from the group consisting of a compound having a nitrogen-containing 5-membered ring structure, and an aminocarboxylic acid having two or more carboxyl groups.

11. The polishing composition according to claim 10, wherein the compound having nitrogen-containing 5-membered ring structure is at least one selected from the group consisting of 1H-benzotriazole, 5-methyl-1H-benzotriazole, 1H-imidazole, and 1H-tetrazole.

12. The polishing composition according to claim 10, wherein the aminocarboxylic acid is at least one selected from the group consisting of diethylenetriamine pentaacetic acid, triethylenetetramine-N,N,N″,N″,N′″,N′″-hexaacetic acid, nitrilotriacetic acid, N-(2-hydroxyethyl)iminodiacetic acid, and N-(2-hydroxyethyl)ethylenediamine-N,N′,N′-triacetic acid.

13. The polishing composition according to claim 10, further comprising a polishing accelerator.

14. The polishing composition according to claim 10, further comprising a surfactant.

15. A method for producing a polishing composition, the method comprising mixing an oxidizing agent with at least one cobalt dissolution inhibitor selected from the group consisting of a compound having a nitrogen-containing 5-membered ring structure, and an aminocarboxylic acid having two or more carboxyl groups.

16. A polishing method of polishing an object to be polished having a layer containing copper and a layer containing cobalt,
the method comprising simultaneously polishing the layer containing copper and the layer containing cobalt using the polishing composition set form in claim 10.

17. A method for producing a substrate, the method comprising a step of polishing an object to be polished having a layer containing copper and a layer containing cobalt by the polishing method set form in claim 16.

18. A substrate obtainable by the method according to claim 17.

19. A polishing method of polishing an object to be polished having a layer containing copper and a layer containing cobalt,
the method comprising simultaneously polishing the layer containing copper and the layer containing cobalt using a polishing composition obtainable by the method set form in claim 15.
